(19) United States
(12) Patent Application Publication
(10) Pub. No.: US 2010/0182015 A1
(43) Pub. Date: Jul. 22, 2010

(54) Apparatus and Method for Calibrating the Sensitivity of a Moisture Sensor

(76) Inventor: Metin Ata Gunsay, Draper, UT (US)

Correspondence Address: GEOFFREY E. DOBBIN, PATENT ATTORNEY, 4278 SOUTH 6220 WEST, WEST VALLEY CITY, UT, 84128-6501, US

(21) Appl. No.: 12/750,641

(22) Filed: Mar. 30, 2010

Related U.S. Application Data
(63) Continuation-in-part of application No. 11/946,162, filed on Nov. 28, 2007.
Application No. 11/946,162 is a continuation-in-part of application No. 11/947,931, filed on Nov. 30, 2007, now abandoned.

(51) Int. Cl. G01R 35/00

(52) U.S. Cl. 324/601

(57) ABSTRACT

The present invention is a method for adjusting the sensitivity of a moisture probe which measures dielectric constant of surrounding media. The method comprises the steps of placing the probe in media and adjusting its depth to alter composite measured dielectric constant of a column of media about a probe blade.

### CROSS-REFERENCES TO RELATED APPLICATIONS

The present application claims priority as a continuation-in-part application of prior filed U.S. application Ser. Nos. 11/946,162, filed on Nov. 28, 2007, and 11/947,931, filed on Nov. 30, 2007. Both applications are incorporated herein by reference in their entirety.

### BACKGROUND OF THE INVENTION

A variety of moisture sensing probes and monitoring devices have been developed, wherein a user monitors bulk materials by inserting an elongated probe into a material being tested. These devices find application in measuring the moisture content of bulk food products, soil in agricultural applications, and the moisture content of soil in potted plants. In the application of monitoring soil, the water hold capacity of soil can vary greatly according to the soil composition. For example, sandy soils often have poor water holding capability.

The most common moisture sensor sold today is a simple probe which measures moisture content of the medium at a point along the blade of the probe, usually the tip of the probe. These probes are adequate to measure moisture at a target depth of a medium, and may be adjusted for average root depth of plants in a targeted area to determine adequate water supply. However these probes cannot measure the moisture content of a medium along the length of the probe as a whole, and therefore give a small sample of information only at the given depth. Measuring the moisture along a given length of the probe, and thus in the entire range of media around the probe, can prove useful for more accurately determining water content and developing watering plans.

Typically, moisture monitoring devices either visually or audibly indicate moisture or dryness after a dry/moist threshold is reached, or they indicate a continuum of moisture levels. In cases where the soil composition varies, the wet/dry threshold needs to be adjusted, or in the case of monitors that display a continuum of moisture levels, the sensitivity of the probe needs to be adjusted to the type of soil being monitored. The ability for a user to change and calibrate the probe sensitivity or threshold of a monitoring device can be critical. In the case of monitoring the soil moisture in a potted plant, some plants require moisture levels different than others. For example, a cactus will require less watering, than other types of houseplants.

There are varying ways of calibrating the sensitivity or threshold of a monitoring device, for example, the most common practice is to use switches, or even magnetic switches to change the internal numerical threshold of the device. Other methods include providing a link to another computer device, which can download the calibration values. These methods add cost and can be cumbersome. These practices can also add to the difficulty of making the device watertight. Other sensors, particularly for plants, measure a threshold moisture level at a particular depth of soil in order to determine the moisture at the roots of the plant.

One method to measure moisture content in a manner consistent with the teachings of this invention is to measure the dielectric constant of the media. Capacitive probes, as described in the patent applications, and other types of probes, such as a TDR probe, are capable of measuring the dielectric constant of surrounding media. Many types of capacitive and transmission line based moisture sensors exist, but none provide an easy or cost effective method or apparatus for varying or arbitrarily setting the sensitivity level. For example, the sensors disclosed in U.S. Pat. Nos. 6,904,789; 5,148,125; 5,445,178; 5,424,649; 5,148,125; 6,981,405; and 6,060,889, do not provide a means or method for varying the actual sensitivity of the measurements. Moisture sensors specifically designed for measuring the soil in potted plants, also suffer from this inability, as can be seen in U.S. Pat. Nos. 4,791,413; 4,268,824; 4,514,722; 4,931,775; 6,202,479; 6,198,398; and 6,700,39.

In view of the foregoing, there is a need for an apparatus and method for calibrating the sensitivity or dry/moist threshold of a moisture sensor, probe or other monitoring device, which keeps the device electronics watertight, is easy to use, requires no external computer link, and is cost effective.

Accordingly, several objects and advantages of the invention are: to simplify and reduce cost of calibrating the sensitivity or dry/wet threshold of a moisture sensor, probe or other monitoring device. Still further objects and advantages will become apparent from a consideration of the ensuing description and drawings.

### SUMMARY OF THE INVENTION

In accordance with the present invention, an apparatus and method for calibrating the sensitivity and moist/dry threshold of a moisture sensor, comprises a moisture sensor, line and text markings along the surface of the probe, for the purpose of calibrating the probe.

To accomplish these objectives, the method for adjusting a moisture probe comprises varying the depth in which the probe is buried in a medium for which moisture content is desired to be measured. In so doing, the probe is partially in the medium and partially in an atmosphere with a vastly smaller dielectric constant than that of the medium. This adjustment, then, varies the sensitivity of the probe as it will measure a composite dielectric constant that varies with the dielectric constant of the medium and the atmosphere and the relative exposure of the medium to each. It should be noted that this application uses a capacitive probe, such as those described in the parent applications, as an example only, as the method will work with other probes capable of measuring dielectric constant.

The more important features of the invention have thus been outlined in order that the more detailed description that follows may be better understood and in order that the present contribution to the art may better be appreciated. Additional features of the invention will be described hereinafter and will form the subject matter of the claims that follow.

Many objects of this invention will appear from the following description and appended claims, reference being made to the accompanying drawings forming a part of this specification wherein like reference characters designate corresponding parts in the several views.

Before explaining at least one embodiment of the invention in detail, it is to be understood that the invention is not limited in its application to the details of construction and the arrangements of the components set forth in the following description or illustrated in the drawings. The invention is capable of other embodiments and of being practiced and carried out in various ways. Also it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

FIG. 1 is a perspective view of an embodiment a moisture sensor for use with the method of the present invention.

FIG. 2 is a perspective view of the moisture sensor of FIG. 1, with the outer covering of the PCB probe removed.

FIG. 3 depicts the moisture sensor of FIG. 1 in use.

### DETAILED DESCRIPTION OF THE PREFERRED EMBODIMENT

With reference now to the drawings, the preferred embodiment of the calibration method is herein described. It should be noted that the articles “a”, “an”, and “the”, as used in this specification, include plural referents unless the content clearly dictates otherwise. It should be noted that this specification describes the method using with a capacitive moisture sensor that measures the dielectric constant of the target medium, such as described in parent application Ser. No. 11/946,162, which has been incorporated by reference. Detailed description of such probes may be found therein.

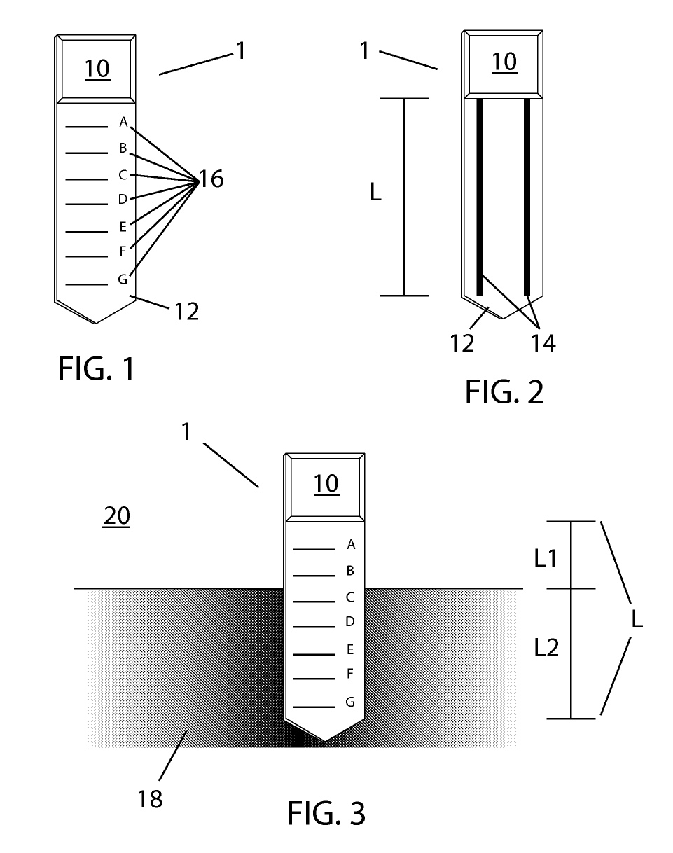

As shown in FIG. 1, a moisture sensor for use in this method 1 is marked with indicia 16, in this case graduated lines and/or text, along the surface of the probe 12. The probe 12 is inserted into the soil or other medium under test. The text labels for each graduation on the diagram is provided as an example, but could be of a form to indicate type of soil or indicate if a plant is to be watered more or less frequently. Any desired and helpful indicia, or even an absence of indicia, may be used. The probe 12 is a PCB board with two parallel conductive traces 14 extending from control unit 10, shown in FIG. 2. The control unit contains the majority of the circuitry as described in the parent application. The traces 16 have a length, L, and extend from the control unit to a distal point on the probe 12.

The control unit 10 is programmed to measure an over-all minimum dielectric constant (or relative permittivity, ∈ᵣ) of a medium measured throughout the length L. It will react in some fashion, be it a visible, audible or electronic signal, when the dielectric constant reaches a minimum threshold, ∈ᵣ≦∈ₜ. Water at room temperature (27° C.) has a dielectric constant ∈_{w}≅78. Air (STP) has a dielectric constant ∈ₐ≅1 that raises slightly as temperature increases. As an example, dry soil has a dielectric constant, ∈ₛ, about the same as air. Its dielectric constant will therefore vary greatly with the amount of water present. When inserted into soil 18, FIG. 3, a portion of the probe tends to remain in the air 20 and the probe reacts to an average dielectric constant ∈ᵣ along L. This dielectric constant is weighted by the proportion of the probe in air L1 and the proportion of the probe in the soil L2. Since ∈_{w}>>∈ₐ, keeping a larger portion of the probe outside the soil will have the effect of reducing ∈ᵣ and inserting the probe further into the soil the converse effect. Likewise, since ∈_{w} is so much greater than ∈ₐ and ∈ₛ, the evaporation of water from the system will drastically reduce ∈ᵣ.

The probe user adjusts the probe sensitivity by inserting the probe more deeply (increasing L2) for applications where the dryness threshold should be lowered, and less deeply (increasing L1) for applications requiring it to be raised. In so doing, the measured ∈ᵣ is raised or lowered until the desired moisture constant in the soil is such that ∈ᵣ=∈ₜ. The method then accounts for different soil types which may retain more or less water than other soil types, different climates, and different plant species which may require more or less water. The user is guided in this calibration by the indicia 16 on the probe 12. Numerous water moisture sensors are available whose sensitivity changes according to insertion depth, and can be used for this application, including those that can be incorporated onto a PCB board; some are transmission line base, others are capacitive in nature.

Accordingly the reader will see that the moisture sensor calibration apparatus, and its associated method, are easy to use, watertight, require no costly switches or computer link. While the above description contains many specifics, these should not be construed as limitations on the scope of the invention, but as exemplifications of the presently preferred embodiments thereof. Many other ramifications and variations are possible within the teachings of the invention. For example, a variety of graduation lines, text and markings could be used. Although the present invention has been described with reference to preferred embodiments, numerous modifications and variations can be made and still the result will come within the scope of the invention. No limitation with respect to the specific embodiments disclosed herein is intended or should be inferred.

What is claimed is:

1. A method of calibrating a moisture sensing probe, said probe sensing moisture through a determination of dielectric constant in media surrounding the probe and having an effective sensing length, L, of the probe, comprising:
a. Placing a probe in a medium for which dielectric constant is to be measured, The probe being inserted therein so that at least a portion of L, L′, is surrounded by the medium, a portion of the medium surrounding the probe being termed surrounding media;
b. Measuring the dielectric constant of the medium and determining an associated moisture content;
c. Altering the measured dielectric constant by changing the depth in which the probe is inserted in the medium and thereby altering an amount of surrounding media about the probe;
Wherein altering the depth in which the probe is inserted in the medium causes a different length of the probe to be exposed to a control medium, such as air, which changes the measured dielectric constant.

2. The method of claim 1, wherein the step of altering the measured dielectric constant is accomplished by moving the probe relative to the medium such that said motion is measured by indicia on the probe.

3. The method of claim 1, wherein the step of altering the measured dielectric constant is accomplished by increasing L′.

4. The method of claim 3, wherein the step of altering the measured dielectric constant by increasing L′ is accomplished by moving the probe relative to the medium such that said motion is measured by indicia on the probe.

5. The method of claim 1, wherein the step of altering the measured dielectric constant is accomplished by decreasing L′.

6. The method of claim 5, wherein the step of altering the measured dielectric constant by decreasing L′ is accomplished by moving the probe relative to the medium such that said motion is measured by indicia on the probe.
